(19) United States
(12) Patent Application Publication
(10) Pub. No.: US 2014/0196759 A1
(43) Pub. Date: Jul. 17, 2014

(54) Two-Sided Solar Cell

(71) Applicant: Scuint Corporation, Austin, TX (US)

(72) Inventor: Steven B Snidow, Austin, TX (US)

(73) Assignee: Scuint Corporation, Austin, TX (US)

(21) Appl. No.: 14/153,055

(22) Filed: Jan. 12, 2014

Related U.S. Application Data
(60) Provisional application No. 61/752,419, filed on Jan. 14, 2013.

(51) Int. Cl. H01L 31/05

(52) U.S. Cl. CPC H01L 31/05
USPC 136/244

(57) ABSTRACT

A solar cell configuration that is comprised of two individual solar cells mounted on a common, rigid, electrical insulator and such that the photoactive sides of the two solar cells are opposite each other and where these elements are integrated into one combined unit and wired together in series or parallel or wired to separate devices and where the electrical insulator may further provide structural integrity to the whole device.

### CROSS-REFERENCE TO RELATED APPLICATIONS

This application claims the benefits of the filing of U.S. Provisional Patent Application Ser. No. 61/752,419 entitled Two-Sided Solar Cell, filed Jan. 14, 2013 and the specification thereof is incorporated herein by reference.

### STATEMENT REGARDING FEDERALLY SPONSORED RESEARCH OR DEVELOPMENT

Not Applicable.

### REFERENCE TO SEQUENCE LISTING, A TABLE, OR A COMPUTER PROGRAM LISTING COMPACT DISK APPENDIX

Not Applicable.

### TECHNICAL FIELD

The present invention is in the technical field of photovoltaic devices. More particularly, the present invention is in the technical field of solar cells.

### BACKGROUND OF THE INVENTION

Conventional solar cell design and manufacturing is comprised of various technologies that normally result in a parallelogram with two opposing planes. One of the two planes may be treated during the manufacturing process to be the negative, or n-type, semiconductor, side. The second plane is the positive side consisting of p-type semiconductor material. A plurality of individual solar cells so formed are then commonly placed on a larger plane forming a solar panel and such that all photo-active sides have the same orientation with the belief that solar cells provide the most energy when set perpendicular to the sun. Commonly, the solar cells are arrayed together in a solar panel that is, itself, either in a fixed position, and able to achieve a maximum gain through only part of the day, or on an adjustable panel that effectively tracks the sun throughout the day. Both approaches require either additional fixed panels or more expensive tracking equipment in order to maximize the generation of electricity.

To help gain more electricity some alternative and more novel approaches for solar cell design and production have been introduced as seen in the following prior art.

U.S. Pat. No. 4,153,476 (Robert A Frosch et al.; May 8, 1979) teaches us of a double-sided solar cell in a glass tube enclosure and teaches us a double-sided solar cell may utilize a common p-type material layer with one side of n-type material and with the opposite side comprised of a second n-type layer that is split in order to allow an armature attachment that acts to raise the whole cell into a centered position within the glass tube. The glass tube then acts to reflect light to the bottom, or split, n-type side of the cell. This patent reflects a two-sided solar cell that is premised on a single p-type material core. Further, this patent reflects a design that splits the second active side losing some of the active capacity while also introducing a conductive armature and relying on glass tubing for light direction.

U.S. Pat. No. 5,665,175 (Yakov Safir; Sep. 9, 1997) teaches us of a bifacial solar cell and the method for final design and manufacture of the bifacial solar cell. Similar to the Frosch et al invention, the Safir invention explains a single bifacial solar cell with a common silicon core formed with two active, doped-silicon, sides that effectively surround the core. The utility of this solar cell should result in an opportunity to generate more electricity. Applications of such a solar cell appear limited due to the brittle structural aspects of most silicon solar cells.

U.S. Pat. No. 6,410,843 (Hitoshi Kishi et al.; Jun. 25, 2002) describes a solar cell module that teaches us the use of bifacial solar cells in a larger module. This invention is comprised of a front transparent surface, a rear surface and a plurality of two-sided incidence solar cells and a reflecting surface all sealed between the front and back surfaces. This patent describes the use of a two-sided cell that is placed into the module with other two-sided cells such that the solar cells are suspended between the surfaces and laterally spaced from each other. The whole module is shown to consist of many bifacial solar cells implying a larger module size that may be comparable to a traditional, one-sided, solar panel. Further, this invention, while utilizing bifacial solar cells arranges such cells in a single plane.

U.S. Pat. No. 6,528,716 (Jean-Paul Collette et al.; Mar. 4, 2003) shows a solar concentrator that teaches us of a saw-tooth pattern with angled reflectors positioned as rows with each row in a triangle configuration and such that light is reflected downward and between each row of reflectors and to a space in between the rows that is occupied by a flat solar cell or row of flat solar cells. This patent addresses the need to place additional light onto solar cells in the attempt to generate more electricity by utilizing critical space for reflectors that may otherwise be utilized by solar cells.

### SUMMARY OF THE INVENTION

The present invention consists of two separate solar cells that are paired such that both photo-active sides are the outward and opposite facing planes and arranged such that the two solar cells are separated by a nonconductive material and otherwise connected together such that the two individual solar cells and electrical insulator layer are made into one unit and then electrically interconnected in parallel, in series or individually to other devices.

The primary objective of the present invention is to increase the amount of electricity generated from silicon, thin film or other forms of solar cells within a defined space and as compared to a one-sided solar cell of the same, or similar, composition and/or manufacture.

The primary advantage of the present invention is the additional electricity generated from the same space already occupied by a single-sided solar cell.

An additional advantage of the present invention is that it may be electrically wired in series or in parallel to provide different levels of volts or amps and then may be further electrically connected to other two-sided solar cells that may be further combined into different electrical profiles.

Another advantage of the present invention is the use of an electrical insulator to separate two solar cells physically and electrically but to also act as a structural aid thus providing the means by which each two-sided solar cell may be positioned, mounted, suspended or otherwise controlled to provide for new solar panel design alternatives.

Other objects, advantages and novel features, and further scope of applicability of the present invention will be set forth in part in the detailed description to follow, taken in conjunction with the accompanying drawings, and in part will become apparent to those skilled in the art upon examination of the following, or may be learned by practice of the invention. The objects and advantages of the invention may be realized and attained by means of the instrumentalities and combinations particularly pointed out in the appended claims.

### BRIEF DESCRIPTION OF THE SEVERAL VIEWS OF THE DRAWING

FIG. 1 is an isometric view of the cross-section of a typical solar cell that is to represent prior art;

FIG. 2 is an isometric and exploded view of the present invention consisting of two opposing solar cells separated by an electrical insulator;

FIG. 3 is an isometric view of the present invention as a final form;

FIG. 4 is an isometric view of the present invention showing the two solar cells wired in series;

FIG. 5 is an isometric view of the present invention showing the two solar cells wired in parallel;

FIG. 6 is an isometric view of the present invention showing the two solar cells wired in parallel with transparent cover and an elongated center insulator; and

FIG. 7 is an isometric and partially exploded view of a solar panel meant to demonstrate one possible use of the present invention.

### DETAILED DESCRIPTION OF THE INVENTION

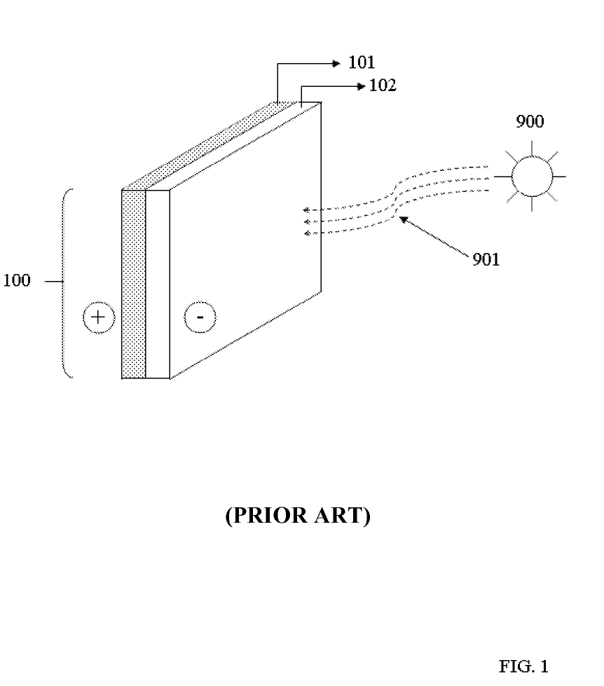

Referring now to FIG. 1, this figure represents a standard and existing solar cell technology and is provided herein to establish the foundation for understanding of the other figures. This isometric view of the cross-section of a typical solar cell 100, such as a silicon-based solar cell, that represents a constituent part of the present invention, and showing p-type semiconductor material 101 and a layer of n-type semiconductor material 102. For the purposes of clarification, light source 900, such as the sun, emits light waves 901 that strike the photo-active cell creating electricity through the photovoltaic process. It should be understood that FIG. 1 is meant to represent prior art.

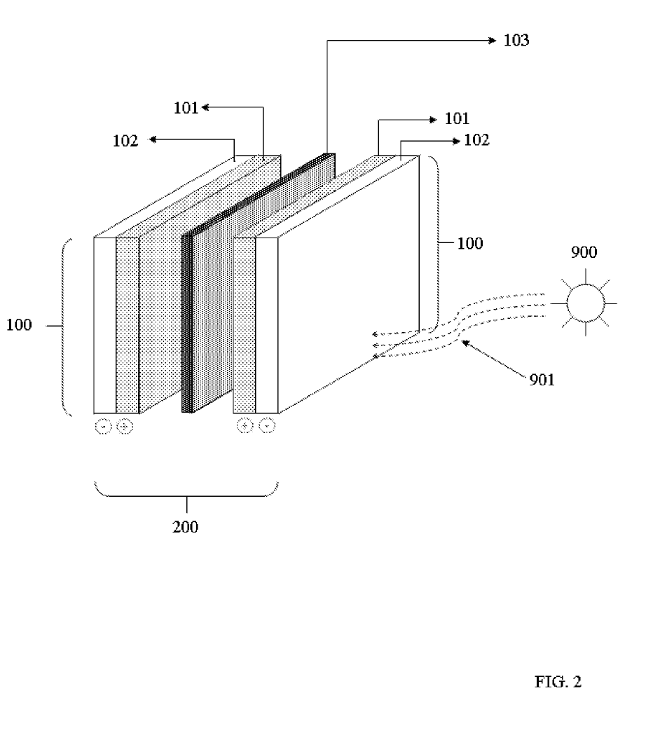

Referring now to FIG. 2, this is the first figure to represent the present invention of a two-sided solar cell 200. FIG. 2 is an exploded and isometric view of the two-sided solar cell 200 that is comprised of typical solar cell 100 with photo-active side facing right paired to a second solar cell 100 with its photo-active side facing left and each with p-type 101 and n-type 102 materials. An electrical insulator 103 separates the two cells and that should be understood may act not only as an electrical insulator but also as a structural element to provide strength and that may be configured in different forms but is shown herein as a sheet. For the purposes of this figure, the method of connection between solar cells 100 and electrical insulator 103 is not shown but can be any combination of an adhesive applied such as a conductive, or non-conductive, glue to the cell-insulator connection or a exterior device to bind the component pieces together. For the purposes of clarification, light source 900, such as the sun, emits light waves 901 that strike both photo-active cells creating electricity through the photovoltaic process.

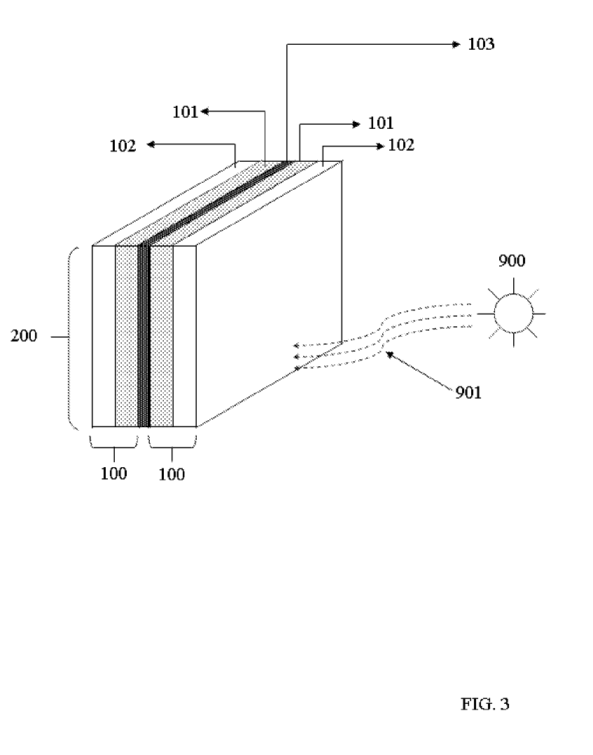

Referring now to FIG. 3 that is an isometric view of the two-sided solar cell 200 with a typical solar cell 100 with photo-active side facing right paired to another solar cell 100 with its photo-active side facing left and each with p-type 101 and n-type 102 materials. An electrical insulator 103 separates the two solar cells 100. This figure is similar to FIG. 2 showing the constituent parts of the present invention placed together in a final form and instead of an exploded view. FIG. 3 is the basis for the following figures. For the purposes of clarification, light source 900, such as the sun, emits light waves 901 that strike the photo-active cell creating electricity through the photovoltaic process and that should be understood to be applicable to the following drawings. It should further be understood that solar cells 100 may be constructed from any selection of, or combination of, different solar cell technologies including, but not limited to, mono-crystalline silicon, multi-crystalline silicon and thin film solar cells.

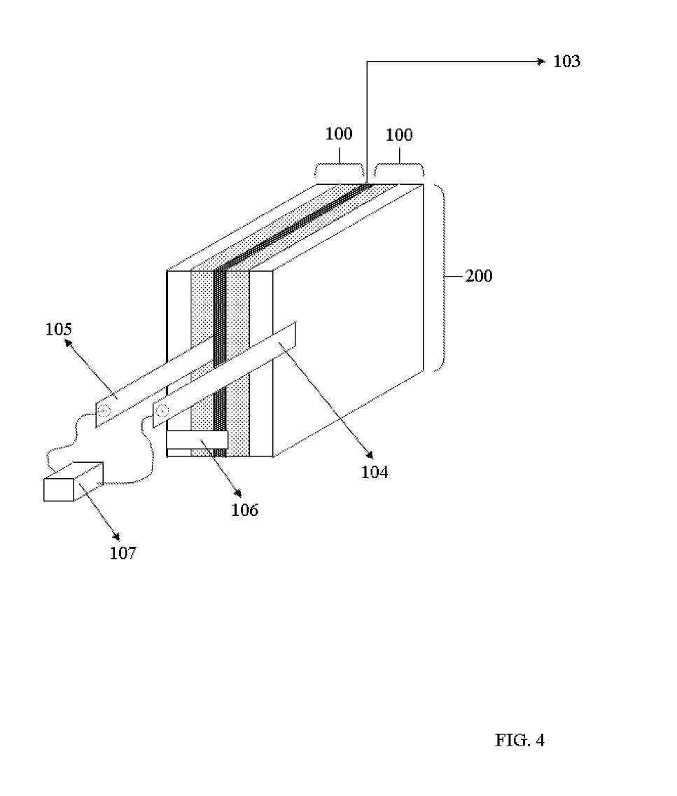

Referring now to FIG. 4 that is an isometric view of the two-sided solar cell 200, as shown in FIG. 3 with electrical insulator 103 separates the two solar cells 100, but also now showing the two solar cells wired in series with a negative electrical lead 104 and a positive electrical lead 105 that connect to a load or other, additional, solar cell combinations 107 and an n-type-to-p-type (negative-to-positive) connection 106 within the unit of the two solar cells 100.

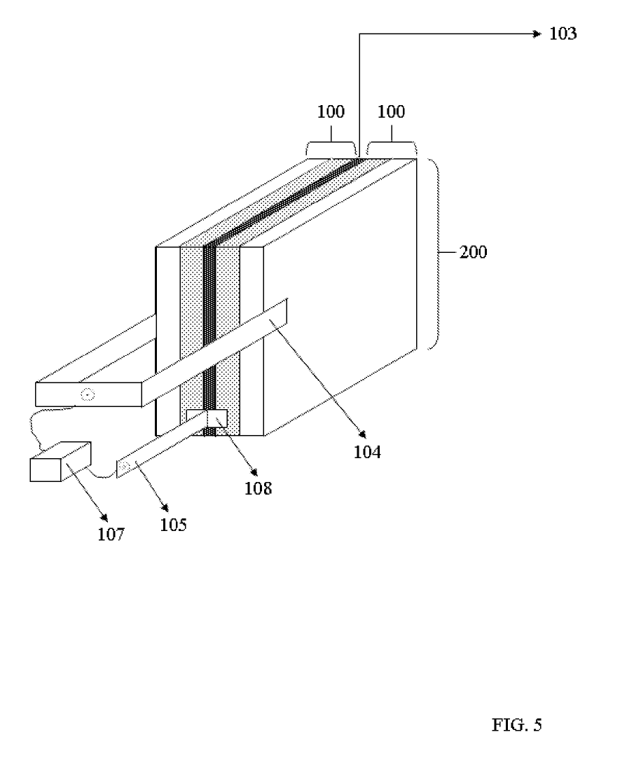

Referring now to FIG. 5 that is an isometric view of the two-sided solar cell 200, as shown in FIG. 3 with electrical insulator 103 separates the two solar cells 100, but also now showing the two cells wired in parallel with a negative electrical lead 104 and a positive electrical lead 105 that connect to a load or other, additional, solar cell combinations 107 and a p-type-to-p-type (positive-to-positive) connection 108 that electrically interconnects the two solar cells 100 and that is further interconnected to the positive lead 105.

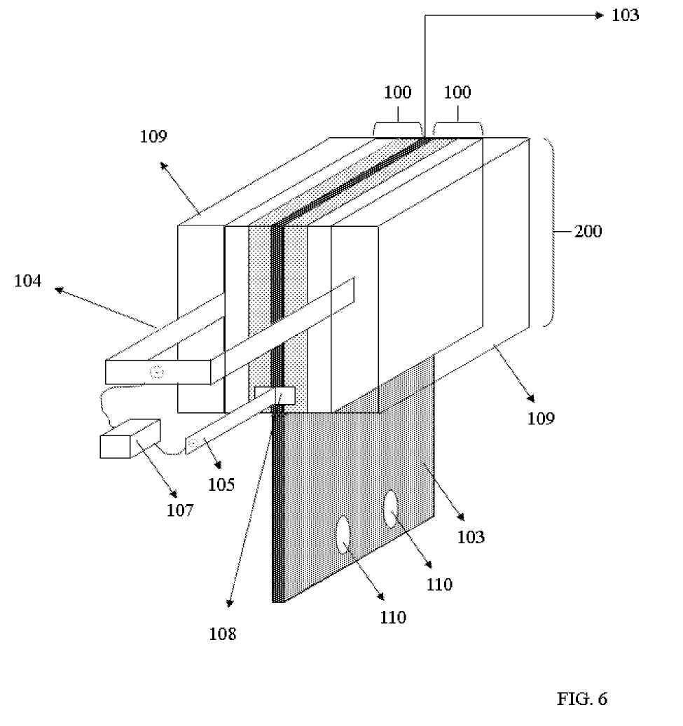

Referring now to FIG. 6 that is an isometric view of the two-sided solar cell 200, as shown in FIG. 5, but also now showing the addition of clear and rigid material covering, 109 such as glass, acrylic, polycarbonate, or other clear and rigid materials, situated to cover, or encapsulate, the two solar cells 100. Electrical insulator 103 is shown extended with mounting holes 110 that should be understood to represent any means of connecting electrical insulator 103 to another surface such as with screws. The other attributes of FIG. 6 are the same as FIG. 5 with an isometric view of the two-sided solar cell 200 but also now showing the two cells wired in parallel with a negative electrical lead 104 and a positive electrical lead 105 that connect to a load or other, additional, solar cell combinations 107 and a p-type-to-p-type (positive-to-positive) connection 108 that electrically interconnects the two solar cells 100 and that is further interconnected to the positive lead 105.

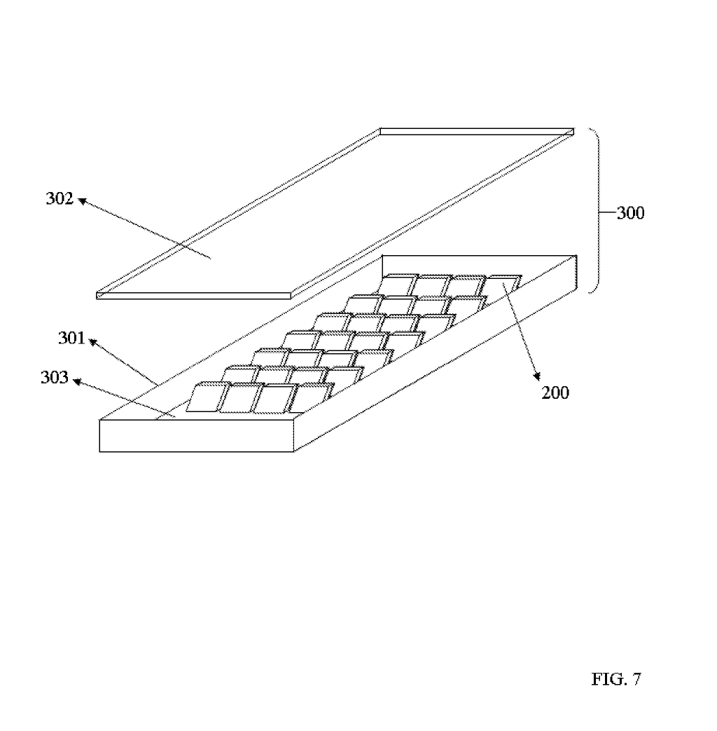

Referring now to FIG. 7 that is an isometric and partially exploded view of solar panel 300. Solar panel 300 is shown to be comprised of a four-sided frame 301, a transparent cover 302, a back substrate 303 and a plurality of two-sided solar cells 200. Two-sided solar cells 200 are arranged into rows of four and mounted at a vertical angle to back substrate 303 and allowing for light to strike both sides of the two-sided solar cells 200. It should be understood that FIG. 7 is meant only to demonstrate one application of the two-sided solar cells 200.

The advantages of the present invention include, without limitation, the ability to increase the amount of electricity production for a given area and allowing for various positions and angles of the present invention to achieve higher energy production.

In broad embodiment, the present invention is two joined solar cells that occupy no more than the same space of one solar cell in a traditional application.

### DESCRIPTION OF THE PREFERRED EMBODIMENTS (BEST MODES FOR CARRYING OUT THE INVENTION)

The present invention should be understood to be either a component of a second device or a device itself. As a device itself, the preferred embodiment of the present invention is to be comprised of at least two solar cells separated by an electrical insulator and where such insulator also acts as a structural member to provide support to the solar cells such that the solar cells are less likely to bend, warp or break. The whole is then, as a preferred embodiment, encased within a cover and electrically interconnected to be adaptable for different end uses such as battery recharging or the recharging of electronic devices.

As a component of a second device, the present invention may manifest many preferred individual embodiments. The common attribute of such embodiments is the effective utilization of each side of the two-sided solar cell(s). In order to provide for more effective utilization of both sides of the present invention, the utility of the electrical insulator layer as a structural component provides for the flat, angled and/or vertical positioning of each two-sided solar cell within a secondary device and where such secondary devices may include individual personal-use devices or larger, appliance-grade, devices.

### INDUSTRIAL APPLICABILITY

The invention is further illustrated by the following non-limiting examples.

### EXAMPLE 1

The present invention may act as a standalone energy device. In its simplest form, the present invention may be comprised of at least two solar cells separated by a structurally rigid electrical insulator and encased in transparent sheets, such as acrylic sheets, and further enclosed by a frame made from plastic, metal or other material. The whole device is electrically connected to a common electrical interconnection such as a USB or mini-USB for the charging of other devices. The present invention, as a standalone device, may be understood to be portable and packable and that may be utilized by an end user in different positions and situations. As a standalone device, the present invention may also be considered to have add-on components such as a stand, clip or other method to secure it to a surface or to another device.

### EXAMPLE 2

The present invention may be used to act as a primary or supplementary electrical power source for end-use devices such as small electrical or small electronic devices. For example, the present invention may be comprised of multiple small two-sided solar cells connected end-on-end and situated into a transparent flashlight handle whose transparent nature allows for light to strike both sides of the two-sided solar cells and increasing the amount of electricity generated over current designs that may embed a single layer of solar cells onto the surface of the flashlight handle. The present invention, as applied in this example, may be considered a supplemental source of electricity and charging the flashlight battery for future use. Placement of the present invention within the flashlight, or other device, may be facilitated by structural aspects of the electrical insulator separating the two individual solar cells.

### EXAMPLE 3

The present invention may be used as a primary or supplemental electrical power source for appliance-grade devices such as for solar panels. As applied to a solar panel, the present invention provides alternative placement of solar cells within the confines of the solar panel. For example, due to the optional structural properties of the electrical insulator layer at the center of the present invention, it is possible to tilt individual, or a plurality of, two-sided solar cells providing for incident light to strike both sides of the present invention and increasing the generation of electricity within the same X-axis and Y-axis dimensions of an otherwise comparable “flat surface” traditional solar panel. Further, the plurality of two-sided solar cells may be wired in series or in parallel, or in a combination of series and parallel, to optimize the generation of electricity.

The preceding examples can be repeated with similar success by substituting the generically or specifically described parameters and/or operating conditions of this invention for those used in the preceding examples.

While the foregoing written description of the invention enables one of ordinary skill to make and use what is considered presently to be the best mode thereof, those of ordinary skill will understand and appreciate the existence of variations, combinations, and equivalents of the specific embodiment, method, and examples herein. The invention should therefore not be limited by the above described embodiment, method, and examples, but by all embodiments and methods within the scope and spirit of the invention as claimed.

I claim:

1. A photovoltaic device comprised of at least one two-sided solar cell that is further comprised such that each two-sided solar cell is formed from two individual solar cells situated with photo-active faces set in opposite directions and separated by a flat electrical insulator and where each solar cell is covered by a clear and rigid material and where the covered solar cells are further bound together by one, or more, means and where the solar cells are electrically interconnected together in series, parallel or electrically interconnected separately and to other devices;

2. A photovoltaic device comprised of at least one two-sided solar cell that is further comprised such that each two-sided solar cell is formed from two individual solar cells situated with photo-active faces set in opposite directions and separated by a flat electrical insulator and where each solar cell is covered by a clear and rigid material and where the covered solar cells are further bound together by one, or more, means and wherein the electrical insulator is a structural support to each solar cell pair and where the solar cells are electrically interconnected together in series, parallel or electrically interconnected separately and to other devices;

3. A photovoltaic device comprised of at least one two-sided solar cell that is further comprised such that each two-sided solar cell is formed from two individual solar cells situated with photo-active faces set in opposite directions and separated by an electrical insulator and where each solar cell is covered by a clear and rigid material and where the covered solar cells are further bound together by one, or more, means and wherein the solar cells are electrically interconnected together in series, parallel or electrically interconnected separately and to other devices and wherein the electrical insulator may be extended from the dimensions of the solar cells to form an armature that separates the two-sided solar cell configuration from a mounting surface and that then may be connected by any means to the mounting surface.
